(19) United States
(12) Patent Application Publication
(10) Pub. No.: US 2009/0203194 A1
(43) Pub. Date: Aug. 13, 2009

(54) TRANSPARENT CONDUCTIVE FILM DEPOSITION APPARATUS, FILM DEPOSITION APPARATUS FOR CONTINUOUS FORMATION OF MULTILAYERED TRANSPARENT CONDUCTIVE FILM, AND METHOD OF FORMING THE FILM

(75) Inventor: Yoshiaki Tanaka, Tokyo (JP)

Correspondence Address: SUGHRUE-265550, 2100 PENNSYLVANIA AVE. NW, WASHINGTON, DC, 20037-3213, US

(73) Assignee: SHOWA SHELL SEKIYU K.K., Tokyo (JP)

(21) Appl. No.: 11/814,527

(22) PCT Filed: Jan. 20, 2006
(86) PCT No.: PCT/JP2006/300888

§ 371 Date: Jul. 23, 2007

(30) Foreign Application Priority Data
Jan. 21, 2005 (JP) 2005-013682

(51) Int. Cl. H01L 21/365; C23C 16/54

(52) U.S. Cl. 438/478; 118/724; 257/E21.463

(57) ABSTRACT

Raw materials are economized and a film deposition rate is improved while maintaining film evenness and high film quality.

A film deposition apparatus for the continuous formation of a multilayered transparent conductive film is provided which comprises a substrate attachment part, a charging part where evacuation is conducted, a multilayer deposition treatment part comprising two or more deposition treatment parts for forming a transparent conductive film on a substrate by the MOCVD method by reacting an organometallic compound (diethylzinc), diborane, and water in a vapor phase, a substrate takeout part, a substrate detachment part, and a setter return part where the substrate setter is returned to the substrate attachment part. Film deposition is successively conducted while moving a substrate sequentially through the parts to form a multilayered transparent conductive film on the substrate. Each deposition treatment part is equipped with nozzles for spraying the organometallic compound, diborane, and water and with a cooling mechanism for cooling the nozzles.

### TECHNICAL FIELD

The present invention relates to film deposition apparatus and a method of film formation for continuously forming a transparent conductive film having a multilayer structure by the MOCVD method.

### BACKGROUND ART

The sputtering method and the metal-organic chemical vapor deposition (MOCVD) method are used in the step of forming a transparent conductive film among solar cell production steps. Reactions in the MOCVD method proceed at low temperatures (200° C. or lower) and it is a chemical vapor deposition method. Because of these, the MOCVD method is a mild film deposition technique which causes no mechanical damage to other thin constituent layers unlike the techniques in which the bombardment of energy particles damages underlying thin constituent layers, such as the sputtering method.

In producing a CIGS type thin-film solar cell, a transparent conductive film is formed over thin constituent layers on the light incidence side thereof. The transparent conductive film formed by the MOCVD method has the function of enhancing the effect (function) of the buffer layer. In the case of the sputtering method, however, the transparent conductive film is known to cause damage to the buffer layer, rather than enhances its effect, and to reduce the performances of the solar cell.

Techniques for forming a transparent conductive film by the MOCVD method have been disclosed (see, for example, patent documents 1 and 2). The techniques disclosed therein comprise heating a substrate on a heated support, evacuating the chamber and allowing the substrate to stand therein for about 20 minutes to make the temperature thereof even, and then conducting film deposition for about 30 minutes by the MOCVD method to thereby deposit a transparent conductive film in about 1 μm. An MOCVD-method film deposition apparatus is described in patent document 3. It has a constitution in which gases are introduced into a quartz reaction tube through a gas introduction opening and gases in the reaction tube are discharged through a gas discharge opening. This reaction tube has a susceptor made of carbon disposed therein, and a substrate is set on this susceptor. This apparatus has a structure in which the susceptor and the substrate are inductively heated with a high-frequency coil disposed outside the reaction tube. In this film deposition apparatus, an alkylaluminum is mainly used as an organometallic compound to be applied to the substrate. This MOCVD-method film deposition apparatus is not one for continuously forming a transparent conductive film having a multilayer structure, and has had a problem that it cannot form a transparent conductive film having a large area. On the other hand, an apparatus for the continuous formation of a thin semiconductor film has been disclosed in which two or more reaction chambers are disposed and film deposition is successively conducted therein (see, for example, patent document 4). However, this apparatus for continuous film deposition is not one for forming a transparent conductive film by the MOCVD method but one for forming a thin semiconductor film. There has been a problem that it is difficult to directly divert such an apparatus for continuously forming a thin semiconductor film to the continuous formation of a transparent conductive film by the MOCVD method.

### Patent Document 1: JP-B-6-14557

### Patent Document 2: JP-A-6-209116

### Patent Document 3: JP-A-2-122521

Patent Document 4: Japanese patent No. 2842551

Furthermore, the related-art MOCVD-method film deposition apparatus include an MOCVD-method film deposition apparatus for an alkylzinc such as that shown in FIG. 5, and nozzles for exclusive use in this apparatus such as those shown in FIG. 6 have been employed.

This apparatus is an apparatus for the batch treatment of substrates. First, the chamber is opened in the air in order to introduce a substrate (hereinafter, a structure comprising a substrate and layers necessary for a CIGS type thin-film solar cell other than a transparent conductive film, which include a light absorption layer and a buffer layer, formed thereon is referred to as substrate). After a substrate is placed on the hot plate, the chamber is brought into a vacuum state. After the substrate has been heated to a set temperature, raw materials (e.g., an organometallic compound, e.g., diethylzinc Zn(C₂H₅)₂, diborane B₂H₆, and pure water H₂O) are introduced through raw-material introduction ports. A carrier gas is used to spray these raw materials over the substrate through nozzles respectively corresponding to the raw materials. A transparent conductive film is deposited on the substrate over a certain time period (in a certain thickness) Thereafter, the feeding of the raw materials is stopped. The chamber is then opened in the air (the internal pressure is returned to atmospheric pressure) and the substrate is taken out. Since the process is a batch treatment, a next substrate is thereafter placed on the hot plate. Subsequently, the same operation as described above is repeated to thereby form a transparent conductive film on the substrate. This apparatus has had the following features 1 to 3.

1. A feature of the nozzles resides in the structure which evenly sprays the organometallic compound, diborane, and pure water in a vacuum, as shown in FIG. 6. There has been a problem that nozzle maintenance is necessary because the temperature of the nozzles rises during growth due to the heat emitted from the hot plate and a deposit accumulates on the nozzles. Furthermore, there has been a problem that since the related-art nozzle structure has spaces between the ejection parts for an organometallic compound, water, and diborane, product accumulation occurs on the back side of the nozzles and even on an upper part of the chamber, resulting in a low efficiency of utilization of the raw materials and the necessity of frequent maintenance.

2. Because a substrate is directly placed on a metallic hot plate in growing a transparent conductive film, the heat distribution of the hot plate directly leads to the distribution of the transparent conductive film. There has hence been a problem that in case where the hot plate has an uneven heat distribution, a transparent conductive film which is uneven in sheet resistance, etc. is formed.

3. The apparatus has only one chamber. There has hence been a problem that the rate of substrate treatment is low and the rate of film deposition is low.

### DISCLOSURE OF THE INVENTION

### Problems that the Invention is to Solve

A first object of the invention, which is for eliminating the problems described above, is to improve the efficiency of utilization of raw materials and to reduce the necessity of maintenance. A second object is to form a transparent conductive film having an even sheet resistance. A third object is to improve the rate of film deposition while maintaining high film quality.

### Means for Solving the Problems

(1) The invention, which is for eliminating the problems described above, provides a transparent-conductive-film deposition apparatus having a film deposition chamber, wherein after the chamber is evacuated, an organometallic compound (alkylzinc Zn(CₙH₂ₙ₊₁; n is an integer)₂; preferably diethylzinc Zn(C₂H₅)₂), diborane (B₂H₆), and water (water vapor) are reacted in a vapor phase while heating a substrate to form a transparent conductive film comprising an n-type semiconductor on the substrate by the metal-organic chemical vapor deposition (MOCVD) method, wherein

diborane and an inert gas are used as a dopant for conductivity regulation and a carrier gas, respectively, and the organometallic compound and pure water are used as raw materials for film deposition, and the apparatus is equipped inside with a group of nozzles of a planar structure comprising pipe-form nozzles which have ejection holes formed on the ejection side thereof for simultaneously or separately spraying the three raw materials consisting of the organometallic compound, diborane, and pure water and are arranged adjacently to each other in the same plane without leaving a space between these, and is further equipped with a nozzle-cooling mechanism which cools the group of nozzles.

(2) The invention provides a in-line type film deposition apparatus for the continuous formation of a multilayered transparent conductive film, which comprises a substrate attachment part where a substrate is attached to a setter in the air, a charging part where evacuation is conducted, a multilayer deposition treatment part comprising two or more deposition treatment parts for forming a multilayered transparent conductive film comprising an n-type semiconductor on the substrate by the metal-organic chemical vapor deposition (MOCVD) method by reacting an organometallic compound (alkylzinc Zn(CₙH₂₊₁; n is an integer)₂; preferably diethylzinc Zn(C₂H₅)₂), diborane (B₂H₆), and water (water vapor) in a vapor phase while heating the substrate, a takeout part where the substrate having the multilayered transparent conductive film in a vacuum is returned to the atmospheric pressure, a substrate detachment part where the substrate having the multilayered transparent conductive film is detached from the setter, and a setter return part where the setter from which the substrate having the multilayered transparent conductive film was detached in the substrate detachment part is returned to the substrate attachment part, and in which film deposition is successively conducted while moving the substrate sequentially through the parts to form the multilayered transparent conductive film comprising a multilayered n-type semiconductor on the substrate, wherein

in each deposition treatment part in the multilayer deposition treatment part, diborane and an inert gas are used as a dopant for conductivity regulation and a carrier gas, respectively, and the organometallic compound and pure water are used as raw materials for film deposition, and the deposition treatment part is equipped inside with a group of nozzles of a planar structure comprising pipe-form nozzles which have ejection holes formed on the ejection side thereof for simultaneously or separately spraying the three raw materials consisting of the organometallic compound, diborane, and pure water and are arranged adjacently to each other in the same plane without leaving a space between these, and is further equipped with a nozzle-cooling mechanism which cools the group of nozzles.

(3) The invention provides the film deposition apparatus for the continuous formation of a multilayered transparent conductive film as described under (2) above, wherein the charging part and the takeout part are equipped with a preheating mechanism and a substrate-cooling mechanism, respectively, whereby a multilayered film having a necessary thickness is formed by two or more deposition treatment parts at an improved film deposition rate.

(4) The invention provides the film deposition apparatus for the continuous formation of a multilayered transparent conductive film as described under (1), (2), or (3) above, wherein the nozzle-cooling mechanism comprises cooling pipes each disposed between nozzles of the group of nozzles without leaving a space between these.

(5) The invention provides the film deposition apparatus for the continuous formation of a multilayered transparent conductive film as described under (1), (2), or (3) above, wherein the nozzle-cooling mechanism comprises either a group of cooling pipes arranged adjacently to each other or a platy cooler, wherein the group of cooling pipes or the platy cooler is disposed on the group of nozzles of a planar structure on the side (back side) opposite to the ejection side.

(6) The invention provides the film deposition apparatus for the continuous formation of a multilayered transparent conductive film as described under (2) above, wherein the setter is a production jig for fixing the substrate and conveying it through each part in the film deposition apparatus and is made of a member having high thermal conductivity (e.g., carbon composite) whose surface is coated with a metallic coating having high thermal conductivity and high mechanical strength (e.g., nickel deposit), wherein the setter has a pin for substrate fixing.

(7) The invention provides an in-line type film deposition method for the continuous formation of a multilayered transparent conducting film comprising a multilayered n-type semiconductor on a substrate, the method comprising: a step in which a substrate is attached to a setter in the air; a step in which the substrate attached to the setter is evacuated; a step in which film deposition by the metal-organic chemical vapor deposition (MOCVD) method comprising reacting an organometallic compound (alkylzinc Zn(CₙH₂ₙ₊₁; n is an integer)₂; preferably diethylzinc Zn(C₂H₅)₂), diborane (B₂H₆), and water (water vapor) in a vapor phase while heating the substrate is repeatedly conducted two or more times to form a multilayered transparent conductive film comprising an n-type semiconductor on the substrate; a step in which the substrate having the multilayered transparent conductive film in a vacuum is returned to the atmospheric pressure; a step in which the substrate having the multilayered transparent conductive film is detached from the setter; and a step in which the setter from which the substrate having the multilayered transparent conductive film was detached is returned to the substrate attachment part.

(8) The invention provides the film deposition method for the continuous formation of a multilayered transparent conductive film as described under (7) above, wherein in the step in which a multilayered transparent conductive film is formed, diborane and an inert gas are used as a dopant for conductivity regulation and a carrier gas, respectively, and the organometallic compound and pure water are used as raw materials for film deposition, and the apparatus is equipped inside with a group of nozzles of a planar structure comprising pipe-form nozzles which have ejection holes formed on the ejection side thereof for simultaneously or separately spraying the three raw materials consisting of the organometallic compound, diborane, and pure water and are arranged adjacently to each other in the same plane without leaving a space between these, and is further equipped with a nozzle-cooling mechanism which cools the group of nozzles.

### ADVANTAGES OF THE INVENTION

In the invention, each deposition treatment part in the multilayer deposition treatment part is equipped inside with a group of nozzles of a planar structure comprising pipe-form nozzles which have ejection holes formed on the ejection side thereof for simultaneously or separately spraying the three raw materials consisting of the organometallic compound, diborane, and pure water and are arranged adjacently to each other in the same plane without leaving a space between these, and is further equipped with a nozzle-cooling mechanism which cools the group of nozzles. Because of this constitution, the group of nozzles have a one-plate structure having no space between the nozzles. As a result, a reaction product can be prevented from accumulating on the nozzles and the efficiency of utilization of raw materials can be improved. Furthermore, the prevention of reaction product accumulation on the nozzles can further reduce the necessity of maintenance.

In the invention, the setter may be made of a member having high thermal conductivity (carbon composite) whose surface is coated with a metallic coating having high thermal conductivity and high mechanical strength (e.g., nickel deposit) This constitution enables an even transparent conductive film to be formed. Furthermore, by disposing pins for substrate fixing on the setter, a substrate having any desired size can be treated.

In the invention, the charging part and the takeout part may be equipped with a preheating mechanism and a substrate-cooling mechanism, respectively. These mechanisms, in combination with the two or more deposition treatment parts, enable a multilayered film to be formed at an improved film deposition rate without deteriorating film quality.

### BEST MODE FOR CARRYING OUT THE INVENTION

The invention provides a film deposition apparatus for continuously forming a multilayered transparent conductive film comprising a multilayered n-type semiconductor on a substrate and a method of the formation thereof. As shown in FIG. 1, this apparatus comprises a substrate attachment part 2 where a substrate A is attached to a setter 7a in the air, a charging part 3 where evacuation is conducted, a multilayer deposition treatment part 4 comprising two or more deposition treatment parts (41 to 4n) for forming a transparent conductive film comprising an n-type semiconductor (e.g., ZnO) on the heated substrate by the metal-organic chemical vapor deposition (MOCVD) method by reacting an organometallic compound (e.g., diethylzinc, Zn(C₂H₅)₂), diborane (B₂H₆), and water (water vapor) in a vapor phase while heating the substrate, a takeout part 5 where the substrate having the multilayered transparent conductive film is discharged into the air (the pressure is returned to the atmospheric pressure), a substrate detachment part 6 where the substrate A having the multilayered transparent conductive film is detached from the setter 7a, and a setter return part 7 where the setter 7a from which the substrate having the multilayered transparent conductive film was detached in the substrate detachment part is returned to the substrate attachment part 2. In this apparatus, film deposition is successively conducted while moving the substrate sequentially through the parts to form a multilayered transparent conductive film comprising a multilayered n-type semiconductor on the substrate.

In each of the deposition treatment parts 41 . . . 4n in the multilayer deposition treatment part 4 shown in FIG. 1, the following chemical reactions occur when a transparent conductive film made of ZnO is formed.

The main reactions are the following 1 and 2.

Zn(C₂H₅)₂+2H₂O→Zn(OH)₂+2C₂H₆ 1

Zn(OH)₂→ZnO+H₂O 2

Diborane (B₂H₆) is incorporated into the ZnO in a slight amount.

Specifically, the following reaction occurs:

Zn(C₂H₅)₂+H₂O+nB₂H₆→ZnO:B+2C₂H₆+nB₂O₃

provided that n is considerably small.

Each of the deposition treatment parts 41 . . . 4n in the multilayer deposition treatment part 4 shown in FIG. 1 is equipped with composite nozzles (group of nozzles) 4A which are in the platy form (one-plate structure) shown in FIG. 2 and spray the reactants undergoing the MOCVD reactions and which have a nozzle-cooling mechanism. The composite nozzles 4A each comprise a first nozzle 4a for spraying an organometallic compound and diborane, a second nozzle 4b for spraying pure water, and a cooling pipe 4c. The nozzles 4a and 4b and the pipe 4c are independent of one another. They each comprise a pipe having a nearly square sectional shape. The composite nozzles 4A have a flat-plate planar structure in which the first nozzles 4a, second nozzles 4b, and cooling pipes 4c are alternately arranged (disposed) closely in this order without leaving a space therebetween. The first nozzles 4a and the second nozzles 4b have small holes (ejection holes) h for spraying the respective reactants, the holes h being formed on the lower side (substrate disposition side) of the nozzles at a certain interval. Incidentally, the nozzles can be modified to the type in which the three reactants, i.e., an organometallic compound, diborane, and pure water, are simultaneously sprayed through the same nozzle or the type in which an organometallic compound, diborane, and pure water are sprayed separately. The sectional shape of the nozzles 4a and 4b and cooling pipes 4c may be another shape, e.g., circle, as long as the nozzles and pipes can be closely disposed without leaving a space therebetween. The cooling pipes shown are an example, and cooling pipes can be disposed in a smaller or larger number than that in the figure. In place of inserting cooling pipes among the group of nozzles as described above, a structure may be employed in which a group of cooling pipes or a platy cooler has been disposed on a group of nozzles on the side (back side) opposite to the ejection side so as to be in contact with the group of nozzles to cool the whole group of nozzles. A feature of the structure resides in that the composite nozzles can be directly cooled independently.

The cooling pipes 4c cool the nozzles 4a and 4b to inhibit an organometallic compound, diborane, and pure water, which are raw materials for film deposition, from reacting around the nozzles. Since the nozzles 4a and 4b and the cooling pipes 4c have a flat-plate (one-plate) structure in which they are closely disposed without leaving a space therebetween, the raw materials do not accumulate on the back side of the nozzles or an upper part of the chamber (the structure functions as an adhesion-preventive plate). Consequently, the amount of the raw materials to be used is reduced. The embodiment described above is one in which ZnO is deposited as a transparent conductive film. In the case of depositing aluminum oxide Al₂O₃, however, the organometallic compound to be used as a raw material is Al(CₙH₂₊₁)₃, preferably Al(CH₃)₃ or Al(C₂H₅)₃.

The setter 7a is a production jig for fixing a substrate and conveying it through each part in the film deposition apparatus, and is made of a member having high thermal conductivity (carbon composite). For the purpose of enhancing the mechanical strength of the carbon material, which has low mechanical strength, a metallic coating having high thermal conductivity and high mechanical strength (e.g., nickel deposit) is applied to the surface thereof. Moreover, pins for substrate fixing are disposed in order to enable the setter to accept a substrate of any size.

The charging part 3 is equipped with a preheating mechanism 3A for heating the substrate from above with a heater, and the takeout part 5 is equipped with a substrate-cooling mechanism 5A for cooling the substrate from below with a cooling plate.

Table 1 given below shows a comparison in the efficiency of utilization of raw materials for a transparent conductive film between the case where a transparent conductive film was formed with the composite nozzles 4A shown in FIG. 2 disposed in each of the deposition treatment parts 41 . . . 4n in the multilayer deposition treatment part 4 of a film deposition apparatus of the invention for the continuous formation of a multilayered transparent conductive film (hereinafter referred to as composite nozzles 4A according to the invention) and the case where a transparent conductive film was formed with the nozzles shown in FIG. 6 in a related-art film deposition apparatus.

TABLE 1
Comparison in efficiency of raw-material utilization between
production apparatus employing nozzles according to the invention
and production apparatus employing related-art nozzles

| | Amount | | | |
|---|---|---|---|---|
| | of raw | Film | Light | Sheet |
| | materials | thick- | trans- | resis- |
| | used | ness | mittance | tance |
| Production apparatus | 0.6 g | 1.2 μm | 88% | 6.5 Ω/□ |
| of the invention | | | | |
| Related-art | 1.0 g | 1.2 μm | 88% | 7.5 Ω/□ |
| production apparatus | | | | |

As shown in Table 1, it was found that the composite nozzles 4A according to the invention are superior in the efficiency of raw-material utilization to the nozzles in a related-art film deposition apparatus.

FIG. 3 shows a comparison in film properties of a transparent conductive film (distribution of sheet resistance) between the case where a transparent conductive film was formed with the film deposition apparatus for the continuous formation of a multilayered transparent conductive film of the invention using the setter made of a carbon composite having high thermal conductivity and the case where a transparent conductive film was formed with a related-art film deposition apparatus in which a substrate was directly set on a hot plate for heating. As shown in FIG. 3, it was found that the transparent conductive film formed using the setter made of a carbon composite in the film deposition apparatus for the continuous formation of a multilayered transparent conductive film of the invention has more even film properties (distribution of sheet resistance) than in the case where a substrate is directly set on a hot plate for heating in a related-art film deposition apparatus. Incidentally, the sheet resistance is evenly distributed in the range of 6-8 [Ω/□].

Table 2 given below shows a comparison in substrate treatment rate between the case where a transparent conductive film was formed with the film deposition apparatus for the continuous formation of a multilayered transparent conductive film of the invention in which the charging part 3 and the takeout part 5 were equipped with a preheating mechanism 3A and a substrate-cooling mechanism 5A, respectively, and the case where a transparent conductive film was formed with a related-art film deposition apparatus.

TABLE 2
Comparison in substrate treatment rate between production apparatus
of the invention and related-art production apparatus

| | | Film | Time period |
|---|---|---|---|
| | | depo- | required for |
| | Substrate | sition | operation other |
| | size | time | than film deposition |
| Production apparatus | 30 cm × 120 cm | 7 min | 0.5 min |
| of the invention | | | |
| Related-art | 30 cm × 120 cm | 16 min | 30 min |
| production apparatus | | | |

As shown in Table 2, it was found that the film deposition apparatus for the continuous formation of a multilayered transparent conductive film of the invention attains a shorter film deposition time than the related-art film deposition apparatus.

Table 3 given below shows a comparison in solar cell characteristics between a CIS type thin-film solar cell employing a transparent conductive film formed with the film deposition apparatus for the continuous formation of a multilayered transparent conductive film of the invention and a CIS type thin-film solar cell employing a transparent conductive film formed with the related-art film deposition apparatus.

TABLE 3
Comparison in solar cell characteristics between CIS
type thin-film solar cell produced with production apparatus
of the invention and CIS type thin-film solar cell produced
with related-art production apparatus

| | | | Open- | Short-circuit |
|---|---|---|---|---|
| | Conversion | | circuit | current |
| | efficiency | Curvature | voltage | density |
| | [%] | factor | [V] | [mA/cm²] |
| Production | 13.2 | 0.66 | 0.57 | 35.1 |
| apparatus | | | | |
| of the invention | | | | |
| Related-art | 12.6 | 0.63 | 0.57 | 35.1 |
| production | | | | |
| apparatus | | | | |

(integrated structure; 30 cm × 120 cm size)

As shown in Table 3, it was found that the film deposition apparatus for the continuous formation of a multilayered transparent conductive film of the invention attains better solar cell characteristics than the related-art film deposition apparatus.

Furthermore, FIG. 4 shows the relationship between film quality (sheet resistance) and the number of film deposition operations in the case where transparent conductive films were continuously formed with the nozzles according to the invention and in the case where transparent conductive films were batchwise formed with the related-art nozzles.

A comparison between the sheet resistances of the transparent conductive films in the case where film deposition was repeatedly conducted batchwise using the related-art nozzles (see FIG. 6) and those in the case where film deposition was continuously conducted using the nozzles according to the invention (see FIG. 2) proved the following. In the case where the related-art nozzles are used, as the number of film deposition operations increases, the nozzles are heated and raw-material feeding onto the substrate decreases, resulting in a decrease in film thickness and hence in an increase in the sheet resistance of the transparent conductive film as shown in FIG. 4. There has hence been a problem that the solar cell has a reduced conversion efficiency. In contrast, in the case where film deposition is continuously conducted with the nozzles according to the invention, the sheet resistance of the transparent conductive film is constant due to the nozzle-cooling mechanism.

### BRIEF DESCRIPTION OF THE DRAWINGS

FIG. 1 is a view showing the constitution of a film deposition apparatus of the invention for the continuous formation of a multilayered transparent conductive film.

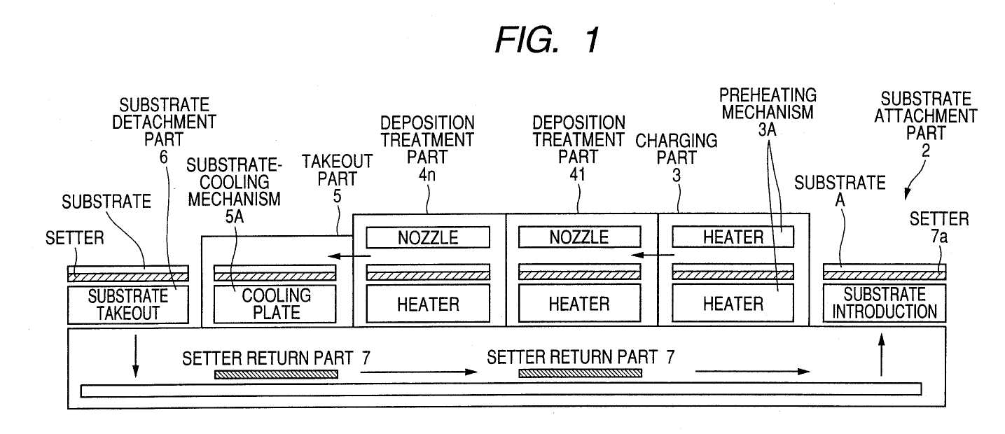

FIG. 2 is a view showing the constitution of the composite nozzles disposed in each of the deposition treatment parts in the multilayer deposition treatment part of the film deposition apparatus of the invention for the continuous formation of a multilayered transparent conductive film.

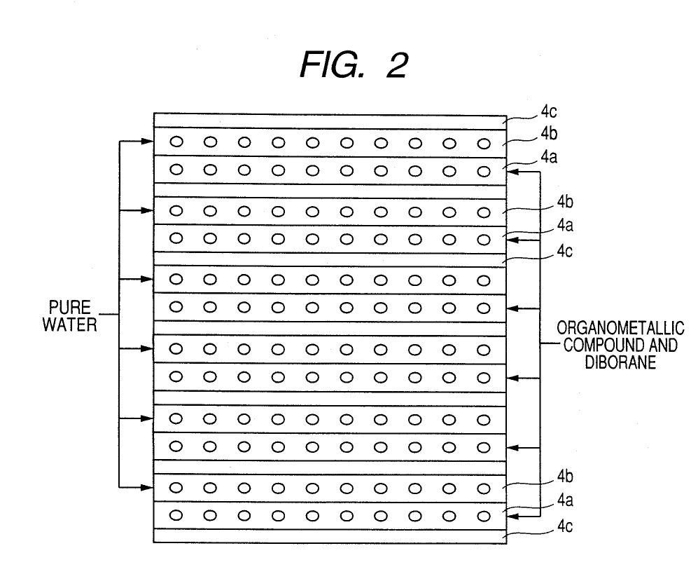

FIG. 3 is views showing a comparison in film properties of a transparent conductive film (distribution of sheet resistance) between the case where a transparent conductive film was formed with the film deposition apparatus for the continuous formation of a multilayered transparent conductive film of the invention using the setter made of a carbon composite having high thermal conductivity and the case where a transparent conductive film was formed with a related-art film deposition apparatus in which a substrate was directly set on a hot plate for heating.

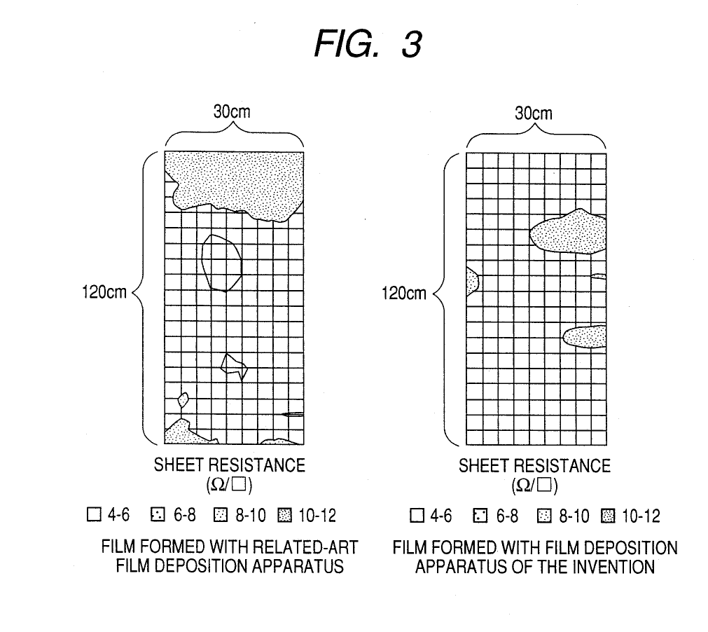

FIG. 4 is a presentation showing the relationship between film quality and the number of repetitions of film deposition in transparent conductive films formed with the nozzles according to the invention and in transparent conductive films formed with related-art nozzles.

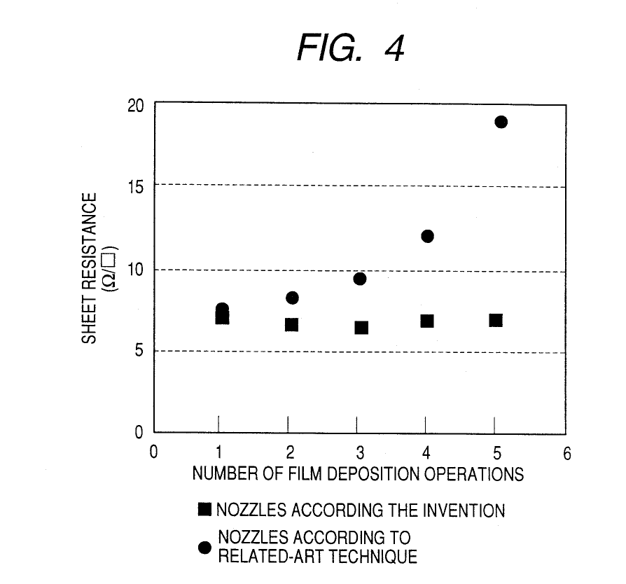

FIG. 5 is a view showing the constitution of a related-art MOCVD apparatus.

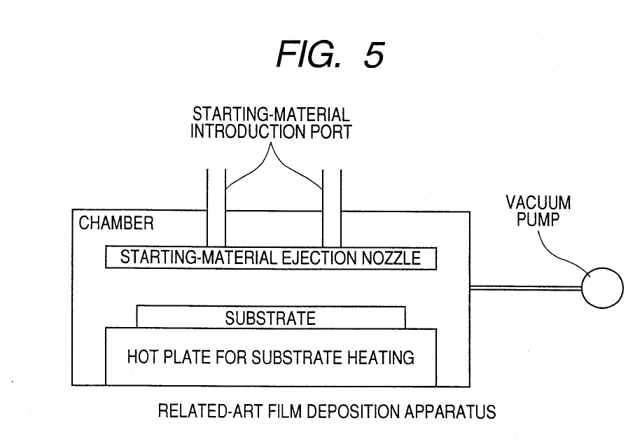

FIG. 6 is a view showing the structure of the nozzles of the related-art MOCVD apparatus.

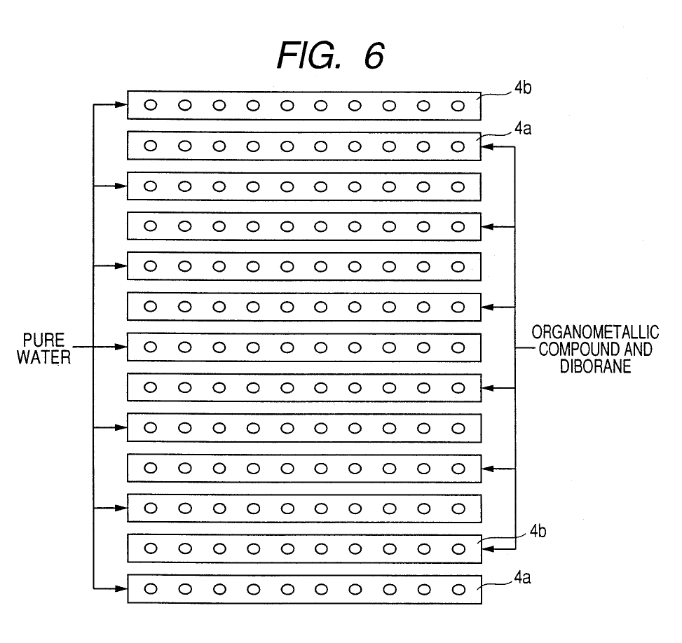

### DESCRIPTION OF THE REFERENCE NUMERALS AND SINGS

1 film deposition apparatus for continuous formation of multilayered transparent conductive film
2 substrate attachment part
3 charging part
3A preheating mechanism
4 multilayer deposition treatment part
41 deposition treatment part
4n deposition treatment part
4A composite nozzle
4a ejection nozzle for organometallic compound and diborane
4b water ejection nozzle
4c cooling pipe
5 takeout part
5A substrate-cooling mechanism
6 substrate detachment part
7 setter return part
7a setter
A substrate

1. A transparent-conductive-film deposition apparatus having a film deposition chamber, wherein after the chamber is evacuated, an organometallic compound (alkylzinc Zn(CₙH₂₊₁; n is an integer)₂; preferably diethylzinc Zn(C₂H₅)₂), diborane (B₂H₆), and water (water vapor) are reacted in a vapor phase while heating a substrate to form a transparent conductive film comprising an n-type semiconductor on the substrate by the metal-organic chemical vapor deposition (MOCVD) method,
wherein diborane and an inert gas are used as a dopant for conductivity regulation and a carrier gas, respectively, and the organometallic compound and pure water are used as raw materials for film deposition, and wherein the apparatus is equipped inside with a group of nozzles of a planar structure comprising pipe-form nozzles which have ejection holes formed on the ejection side thereof for simultaneously or separately spraying the three raw materials consisting of the organometallic compound, diborane, and pure water and are arranged adjacently to each other in the same plane without leaving a space between these, and is further equipped with a nozzle-cooling mechanism which cools the group of nozzles.

2. An in-line type film deposition apparatus for the continuous formation of a multilayered transparent conductive film, which comprises a substrate attachment part where a substrate is attached to a setter in the air, a charging part where evacuation is conducted, a multilayer deposition treatment part comprising two or more deposition treatment parts for forming a multilayered transparent conductive film comprising an n-type semiconductor on the substrate by the metal-organic chemical vapor deposition (MOCVD) method by reacting an organometallic compound (alkylzinc: Zn(C_{b}H₂₊₁; n is an integer)₂; preferably diethylzinc: Zn(C₂H₅)₂), diborane (B₂H₆), and water (water vapor) in a vapor phase while heating the substrate, a takeout part where the substrate having the multilayered transparent conductive film in a vacuum is returned to the atmospheric pressure, a substrate detachment part where the substrate having the multilayered transparent conductive film is detached from the setter, and a setter return part where the setter from which the substrate having the multilayered transparent conductive film was detached in the substrate detachment part is returned to the substrate attachment part, and in which film deposition is successively conducted while moving the substrate sequentially through the parts to form the multilayered transparent conductive film comprising a multilayered n-type semiconductor on the substrate,
wherein in each deposition treatment part in the multilayer deposition treatment part, diborane and an inert gas are used as a dopant for conductivity regulation and a carrier gas, respectively, and the organometallic compound and pure water are used as raw materials for film deposition, and that the deposition treatment part is equipped inside with a group of nozzles of a planar structure comprising pipe-form nozzles which have ejection holes formed on the ejection side thereof for simultaneously or separately spraying the three raw materials consisting of the organometallic compound, diborane, and pure water and are arranged adjacently to each other in the same plane without leaving a space between these, and is further equipped with a nozzle-cooling mechanism which cools the group of nozzles.

3. The film deposition apparatus for the continuous formation of a multilayered transparent conductive film according to claim 2, wherein the charging part and the takeout part are equipped with a preheating mechanism and a substrate-cooling mechanism, respectively, whereby a multilayered film having a necessary thickness is formed by two or more deposition treatment parts at an improved film deposition rate.

4. The film deposition apparatus for the continuous formation of a multilayered transparent conductive film according to claim 1, 2, or 3, wherein the nozzle-cooling mechanism comprises cooling pipes each disposed between nozzles of the group of nozzles without leaving a space between these.

5. The film deposition apparatus for the continuous formation of a multilayered transparent conductive film according to claim 1, 2, or 3, wherein the nozzle-cooling mechanism comprises either a group of cooling pipes arranged adjacently to each other or a platy cooler, wherein the group of cooling pipes or the platy cooler is disposed on the group of nozzles of a planar structure on the side (back side) opposite to the ejection side.

6. The film deposition apparatus for the continuous formation of a multilayered transparent conductive film according to claim 2, wherein the setter is a production jig for fixing the substrate and conveying it through each part in the film deposition apparatus and is made of a member having high thermal conductivity (e.g., carbon composite) whose surface is coated with a metallic coating having high thermal conductivity and high mechanical strength (e.g., nickel deposit), the setter has a pin for substrate fixing.

7. An in-line type film deposition method for the continuous formation of a multilayered transparent conducting film comprising a multilayered n-type semiconductor on a substrate, the method comprising: a step in which a substrate is attached to a setter in the air; a step in which the substrate attached to the setter is evacuated; a step in which film deposition by the metal-organic chemical vapor deposition (MOCVD) method comprising reacting an organometallic compound (alkylzinc: Zn(CₙH₂ₙ₊₁; n is an integer)₂; preferably diethyl zinc: Zn(C₂H₅)₂), diborane (B₂H₆), and water (water vapor) in a vapor phase while heating the substrate is repeatedly conducted two or more times to form a multilayered transparent conductive film comprising an n-type semiconductor on the substrate; a step in which the substrate having the multilayered transparent conductive film in a vacuum is returned to the atmospheric pressure; a step in which the substrate having the multilayered transparent conductive film is detached from the setter; and a step in which the setter from which the substrate having the multilayered transparent conductive film was detached is returned to the substrate attachment part.

8. The film deposition method for the continuous formation of a multilayered transparent conductive film according to claim 7, wherein in the step in which a multilayered transparent conductive film is formed, diborane and an inert gas are used as a dopant for conductivity regulation and a carrier gas, respectively, and the organometallic compound and pure water are used as raw materials for film deposition, and wherein the apparatus is equipped inside with a group of nozzles of a planar structure comprising pipe-form nozzles which have ejection holes formed on the ejection side thereof for simultaneously or separately spraying the three raw materials consisting of the organometallic compound, diborane, and pure water and are arranged adjacently to each other in the same plane without leaving a space between these, and is further equipped with a nozzle-cooling mechanism which cools the group of nozzles.
